(19) United States
(12) Patent Application Publication
(10) Pub. No.: US 2017/0334166 A1
(43) Pub. Date: Nov. 23, 2017

(54) BARRIER LAMINATE, GAS BARRIER FILM, AND DEVICE EMPLOYING THE SAME

(71) Applicant: FUJIFILM Corporation, Tokyo (JP)

(72) Inventors: Hiroshi KAWAKAMI, Kanagawa (JP); Toshihide AOSHIMA, Kanagawa (JP)

(73) Assignee: FUJIFILM Corporation, Tokyo (JP)

(21) Appl. No.: 15/665,830

(22) Filed: Aug. 1, 2017

Related U.S. Application Data
(62) Division of application No. 14/185,536, filed on Feb. 20, 2014.
Application No. 14/185,536 is a continuation of application No. PCT/JP2012/074564, filed on Sep. 25, 2012.

(30) Foreign Application Priority Data
Sep. 26, 2011 (JP) 2011-209076

(51) Int. Cl. B32B 7/02; B32B 27/38; H01L 31/0392; H01L 51/52; H01L 51/44; B65D 33/00; H01L 31/049; B65D 30/08

(52) U.S. Cl. CPC B32B 7/02; B65D 33/00; B32B 27/38; H01L 31/049; H01L 31/0392; H01L 51/5275; H01L 51/5253; H01L 51/448; B65D 31/02; Y10T 428/24942; Y10T 428/1341; Y02E 10/549

(57) ABSTRACT

The present invention provides a barrier laminate, comprising an organic layer and an inorganic barrier layer adjacent to the organic layer, characterized in that the organic layer comprises a polymer obtained by polymerizing a polymerizable compound having two or more polymerizable groups per molecule, and has a refractive index of 1.60 or higher, and in that the refractive index of the inorganic barrier layer is 1.60 or higher. The gas barrier film exhibits high barrier properties and transparence.

### CROSS-REFERENCE TO RELATED APPLICATIONS

This application is a continuation of PCT/JP2012/074564, which claims priority to Japanese Patent Application No.2011-209076 filed on Sep. 26, 2011, the entire contents of which are incorporated herein by reference.

### TECHNICAL FIELD

The present invention relates to a barrier laminate, a gas barrier film, and a device employing the same.

### BACKGROUND ART

Conventionally, gas barrier films in which a metal oxide thin film of aluminum oxide, magnesium oxide, silicon oxide, silicon nitride, silicon oxynitride, or the like is formed on the surface of a plastic film have been widely employed in the packaging of products requiring the blocking of various gases such as water vapor and oxygen, and in packaging applications to prevent the deterioration of foods, industrial products, pharmaceuticals, and the like.

In recent years, the need for transparent gas barrier films to replace glass substrates has been increasing in the field of organic devices such as organic EL devices, organic solar cell devices, and organic TFT devices. Transparent gas barrier films are lightweight and are suited to roll-to-roll methods, which is advantageous in terms of cost. However, transparent gas barrier films present a problem in the form of inferior water vapor barrier properties relative to glass substrates.

To solve this problem, Patent Reference 1 discloses a technique of achieving water vapor permeability of less than 0.005 g/m² day by means of a laminate of multiple alternating layers of an organic layer and an inorganic barrier layer (a barrier laminate). According to Patent Reference 1, when only a single organic layer and a single inorganic barrier layer are stacked, the water vapor permeability is 0.011 g/m²/day. Thus, the technical value of stacking multiple layers is clearly indicated.

However, with the technique of Patent Reference 1, the stacking of multiple layers increases light reflection at the interface between layers, compromising transparence.

Patent Reference 2 discloses a technique of optimizing the relative relationship between the refractive indexes of the various layers that are stacked as a means of solving the deterioration in transparence due to stacking multiple layers. Specifically, in Patent Reference 2, stacking is conducted with a layer having a high refractive index as a lower layer close to the substrate film and a layer with a low refractive index as an upper layer. Thus, the discoloration due to light reflecting at the interface between layers is reduced. However, with this technique, to satisfy the requirement that the refractive index of the upper layer be higher than that of the lower layer, there is a limitation that a material with a low refractive index be used in the inorganic barrier layer. The present inventors have discovered that the higher the density and the higher the refractive index of the material of the inorganic barrier layer, the higher the barrier properties tend to be. Thus, the limitation of Patent Reference 2 is disadvantageous for obtaining high barrier properties. Thus, a technique that yields high barrier properties even when only a small number of layers are stacked has been sought.

Patent Reference 3 discloses a technique of using a polymer with a high glass transition temperature (Tg) and high plasma resistance in the organic layer as a means of achieving good barrier properties in a laminate of few layers. Specifically, a structure is adopted such that the molecular structure of a polymerizable compound that is the precursor of a polymer is imparted with a high ratio of aromatic rings and numerous polymerizable groups.

The technique of Patent Reference 2 is an effective means of enhancing barrier properties. However, to achieve the water vapor permeability of 1×10⁻⁴ g/m²/day or less that is required by organic devices requires laminating at least two sets of an organic layer and an inorganic layer, and a problem of high haze still remains.

### PRIOR ART REFERENCES

Patent Reference 1: U.S. Pat. No. 6,413,645

Patent Reference 2: Japanese Unexamined Patent Publication (KOKAI) No. 2007-76207

Patent Reference 3: Japanese Unexamined Patent Publication (KOKAI) No. 2010-228446

### SUMMARY OF THE INVENTION

### Problem to be Solved by the Invention

In light of the above circumstances, the present invention has for its object to solve the problem of achieving both high barrier properties and transparence, and to provide a transparent gas barrier film affording such performance at low cost.

### Means of Solving the Problem

Based on the above problem, the present inventors conducted extensive research. This resulted in the discovery that the above problem was solved by means <1> below, preferably means <2> to <10> below.

<1> A barrier laminate, comprising an organic layer and an inorganic barrier layer adjacent to the organic layer, characterized in that the organic layer comprises a polymer obtained by polymerizing a polymerizable compound having two or more polymerizable groups per molecule, and has a refractive index of 1.60 or higher, and in that the refractive index of the inorganic barrier layer is 1.60 or higher.
<2> The barrier laminate according to <1>, wherein the inorganic barrier layer comprises an oxide, nitride, carbide, or mixture thereof, that contains silicon,
<3> The barrier laminate according to <1> or <2>, wherein the organic layer comprises a polymer obtained by polymerizing a polymerizable composition comprising a silane coupling agent.

<4> The barrier laminate according to any one of <1> to <3>, wherein the polymerizable compound is at least one member selected from the group consisting of general formulas (1) to (4) below:

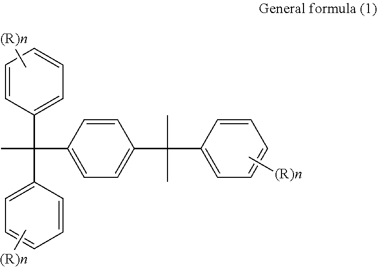

in general formula (1), each instance of R denotes a substituent, each of which may be identical to or different from the others, n denotes an integer of from 0 to 5, with at least one of the three instances of n denoting an integer of 1 or more, with each instance being identical to or different from the others, and at least one instance of R contains a polymerizable group;

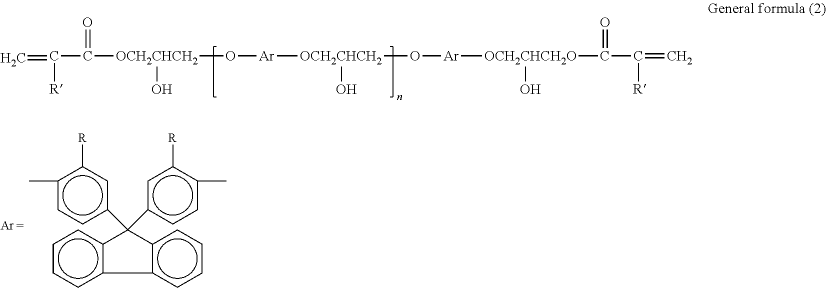

in general formula (2), R denotes hydrogen atom or a lower alkyl group, R′ denotes hydrogen atom or methyl group, and n denotes an integer of from 0 to 20;

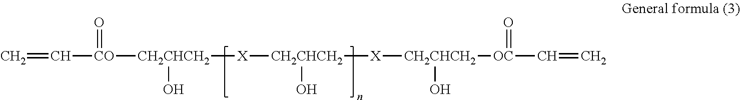

in general formula (3), X denotes a unit represented by formula (3a) below and n denotes an integer of from 0 to 20:

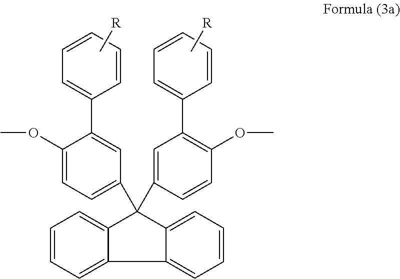

in formula (3a), R denotes hydrogen atom or a linear or branched alkyl group with 1 to 5 carbon atoms; and

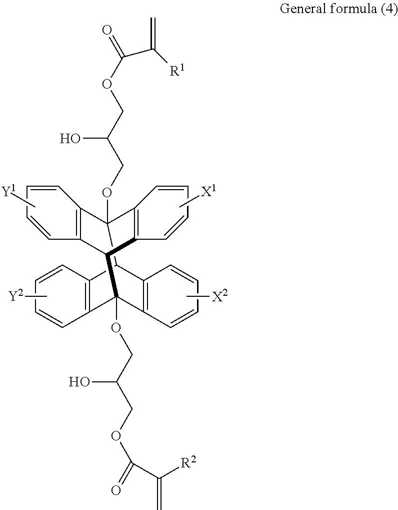

in general formula (4), each of R¹ and R² denotes hydrogen atom or methyl group, and each of X¹, X², Y¹, and Y², which may be identical or different, denotes hydrogen atom, an alkyl group, a halogen atom, an alkoxy group, an aryloxy group, an alkylthio group, or an arylthio group;
<5> The barrier laminate according to any one of <1> to <4>, wherein at least two layers of the organic layer and at least two layers of the inorganic barrier layer are laminated in alternating fashion.
<6> A gas barrier film having the barrier laminate according to any one of <1> to <5> on a substrate film.
<7> A device having the barrier laminate according to any one of <1> to <5> or the gas barrier film according to <6>.
<8> The device according to <7> wherein the device is an electronic device.
<9> The device according to <8>, wherein the device is an organic EL element or a solar cell element.
<10> A sealing bag employing the barrier laminate according to any one of <1> to <5> or the gas barrier film according to <6>.

### Effect of the Invention

By adopting the organic layer in the present invention, it becomes possible to provide a barrier laminate that achieves both high barrier properties and transparence.

### MODE OF CARRYING OUT THE INVENTION

The present invention will be described in greater detail below. In the present Description, the word “to” in a numeric range is used to mean a range that includes the preceding and succeeding numbers as minimum and maximum values, respectively. In the present invention, the term “organic EL element” means an organic electroluminescent element. In the present Description, the term “(meth)acrylate” is used to mean both “acrylate” and “methacrylate.”

In the present invention, the term “refractive index” refers, as is the general custom, to light with a wavelength of 589.3 nm (sodium D-ray).

### <The Barrier Laminate>

The gas barrier film laminate of the present invention comprises an organic layer and an inorganic barrier layer adjacent to the organic layer, and is characterized in that the organic layer comprises a polymer, obtained by polymerizing a polymerizable compound having two or more polymerizable groups per molecule, and has a refractive index of 1.60 or higher, and in that the inorganic barrier layer has a refractive index of 1.60 or higher. Adopting such a form makes it possible to simultaneously achieve enhanced gas barrier properties and a reduction in haze. Here, the phrase “the organic layer is adjacent to the inorganic barrier layer” means either that the organic layer is positioned on the surface of the inorganic barrier layer or that the inorganic barrier layer is positioned on the surface of the organic layer.

The haze reducing effect in the present invention is understood to arise from a qualitative reduction in the difference between the refractive index of the organic layer and the inorganic barrier layer adjacent to the organic layer, resulting in little reflection of light at the interface between the organic layer and the inorganic barrier layer. Here, when a material with a low refractive index of less than 1.60 is employed in the inorganic barrier layer to reduce the difference between the refractive index of the adjacent organic layer and the inorganic barrier layer, there is a problem in that it is difficult to achieve high barrier properties. In light of this problem, the present invention ensures transparence of the barrier laminate by keeping the refractive index of the organic layer to 1.60 or higher while ensuring high barrier properties by using a material having a high refractive index of 1.60 or higher in the inorganic barrier layer.

Unexpected effects are also achieved in that not just transparence, but the barrier properties, as well, is enhanced by having a refractive index of 1.60 or more in the organic layer. In that regard, it is surmised that by increasing the density of the organic layer to where it has a refractive index of 1.60 or higher, damage from plasma or heat during formation of the inorganic layer tends not to occur. However, a full understanding of this point has not yet been achieved.

### (The Organic Layer)

An example of a specific means of causing the organic layer to comprise a polymer obtained by polymerizing a polymerizable compound having two or more polymerizable groups per molecule and to have a refractive index of 1.60 or higher includes a method in which the organic layer is formed by polymerizing a composition containing one or more of the polymerizable compounds denoted by general formulas (1) to (4) below.

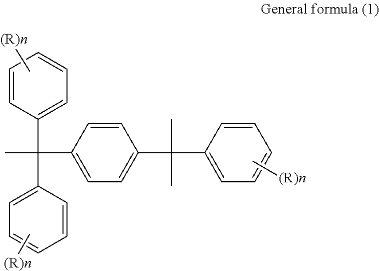

In general formula (1), each instance of R denotes a substituent, each of which may be identical to or different from the others. n denotes an integer of from 0 to 5, with at least one of the three instances of n denoting an integer of 1 or more, with each instance being identical to or different from the others. At least one instance of R contains a polymerizable group.

Examples of substituent R include a group comprised of a combination of one or more from among —CR₂¹—(wherein R¹ is a hydrogen atom or a substituent), —CO—, —O—, phenylene group, —S—, —NR²—(wherein R² is a hydrogen atom or a substituent), and —CR³═CR₂¹—(wherein each of R³ and R⁴ denotes a hydrogen atom or a substituent) with a polymerizable group. A group comprised of a combination of one or more from among —CR₁²—(wherein R¹ is a hydrogen atom or a substituent), —CO—, —O—, and —NR²—(wherein R² is a hydrogen atom or a substituent) with a polymerizable group is preferable.

Examples of each of R, when R is a substituent containing no polymerizable groups, and the substituents denoted by R¹ and R² include a hydrogen atom, alkyl group, halogen atom, alkoxy group, and alkylthio group. Each preferably denotes a hydrogen atom, an alkyl group with 5 or fewer carbon atoms, an alkoxy group, or an alkylthio group, and more preferably denotes a hydrogen atom or an alkyl group with 3 or fewer carbon atoms.

R¹ denotes a hydrogen atom or a substituent, and is preferably a hydrogen atom or a hydroxy group.

R is preferably bonded at the pare position at least.

Each instance of n denotes an integer of from 0 to 5, preferably an integer of from 0 to 2, and more preferably 0 or 1. In the present invention, it is particularly desirable for all three instances of n to denote 1.

In the compound denoted by general formula is desirable for at least two of the instances of R to denote identical structures.

It is preferable for all the instances of n to denote 1 and for at least two of the three instances of R to denote an identical structure, and more preferably for all the instances of n to denote 1 and for all three instances of R to denote an identical structure.

The polymerizable group that is present in general formula (1) is preferably a (meth)acryloyl group or an epoxy group, and more preferably a (meth)acryloyl group. The number of polymerizable groups present in general formula (1) is preferably three or more. The upper limit is not specifically defined, but six or fewer is preferable.

In the present invention, it is possible for just one compound denoted by general formula (1) to be incorporated, or for two or more to be incorporated. An example of the incorporation of two or more includes a composition containing compounds including different numbers of instances of R of identical structure, and isomers thereof.

Specific examples of compounds of general formula (1) are given below. However, the present invention is not limited thereby. The compounds given below are examples of when all three instances of n in general formula (1) denote 1. However, examples of preferable compounds of the present invention include the cases where one or two of the three instances of n in general formula (1) denote 0 (such as monofunctional and bifunctional compounds), and the cases where one or two of the three instances of n denote 2 or more (two or more instances of R¹ are bonded to a single ring) (for example, tetrafunctional and pentafunctional compounds).

| | Structure formula | |
|---|---|---|
| Compound no. | Core structure | R moiety |
| AC41 AC42 AC43 | 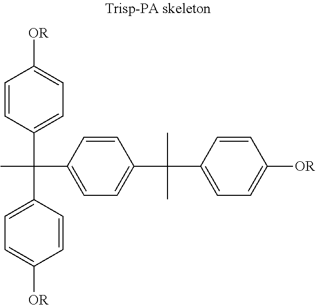 | 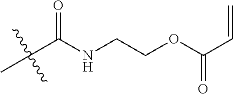 [SMILES: *C(=O)NCCOC(=O)C=C] 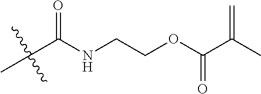 [SMILES: *C(=O)NCCOC(=O)C(=C)C] 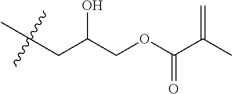 [SMILES: *CC(O)COC(=O)C(=C)C] |
| AC44 | | 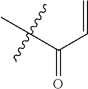 [SMILES: *C(=O)C=C] |
| AC45 | | 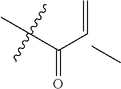 |

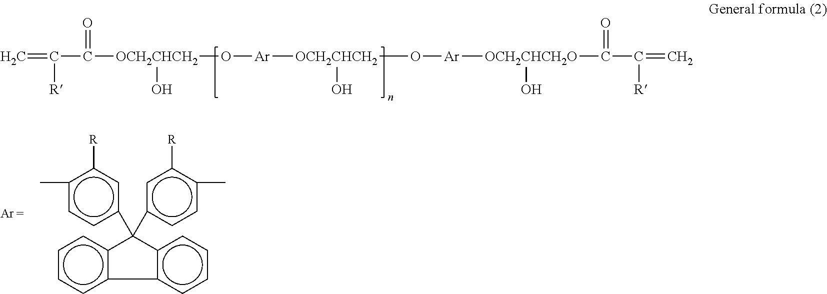

In general formula (2), R denotes a hydrogen atom or a lower alkyl group, and R′ denotes a hydrogen atom or a methyl group. n denotes an integer of from 0 to 20.

An alkyl group with 1 to 5 carbon atoms is preferable and a methyl group or ethyl group is more preferable as the lower alkyl group denoted by R,

As the value of n increases, the viscosity increases and handling becomes difficult. Thus, n is desirably 0 to 2.

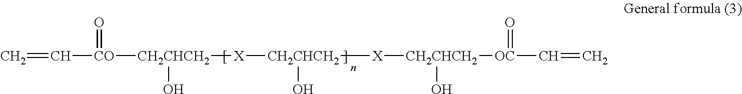

In general formula (3), X denotes he unit represented by formula (3a) below and n denotes an integer of from 0 to 20.

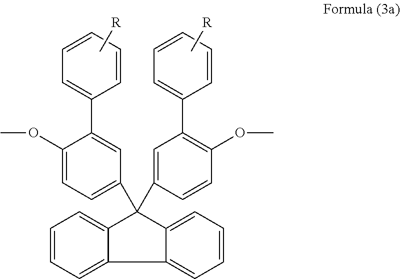

In formula (3a), R denotes a hydrogen atom or a linear or branched alkyl group with 1 to 5 carbon atoms).

R preferably denotes a hydrogen atom, methyl group, or ethyl group, and more preferably denotes a hydrogen atom. As the value of n increases, the viscosity increases and handling becomes difficult. Thus, n is preferably 0 to 2, more preferably 0.

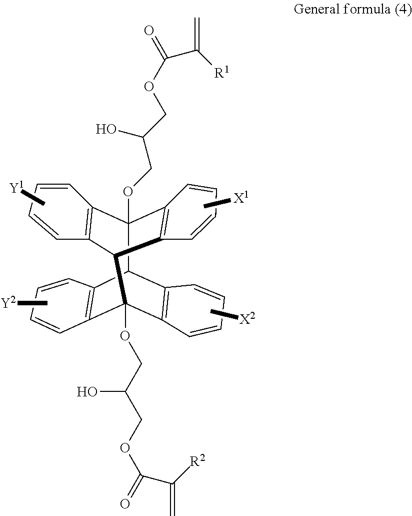

In general formula (4), each of R¹ and R² denotes a hydrogen atom or a methyl group, and each of X¹, X², Y¹, and Y², which may be identical or different, denotes a hydrogen atom, alkyl group, halogen atom, alkoxy group, aryloxy group, alkylthio group, or arylthio group.

Each of X¹, X², Y¹, and Y² preferably denotes a hydrogen atom, alkyl group with three or fewer carbon atoms, alkoxy group with three or fewer carbon atoms, or alkylthio group with three or fewer carbon atoms, and more preferably denotes a hydrogen atom.

### (The Polymerizable Composition)

The organic layer in the present invention is preferably obtained by curing a polymerizable composition comprising one or more of the compounds denoted by general formulas (1) to (4) above. In addition to polymerizable compounds denoted by general formulas (1) to (4), the polymerizable composition employed in the present invention can also contain other polymerizable compounds, photopolymerization initiators, solvents, and other additives. The ratio based on solid fraction (the portion remaining after volatilization of volatile components) accounted for in the polymerizable composition by the polymerizable compound denoted by any of general formulas (1) to (4) and other polymerizable compounds is normally 70 weight % or more, preferably 80 weight % or more, and more preferably 90 weight % or more. The ratio based on solid fraction accounted for in the polymerizable composition by the polymerizable compound denoted by general formulas (1) to (4) is preferably 50 to 99 weight %, more preferably 90 to 98 weight %.

Known polymerizable compounds can be broadly employed as other polymerizable compounds in the present invention. (Meth)acrylates are preferable and (meth)acrylates comprising aromatic groups are particularly preferable.

Specific examples of (meth)acrylates that can be employed in combination in the present invention are given below. The present invention is not limited thereto.

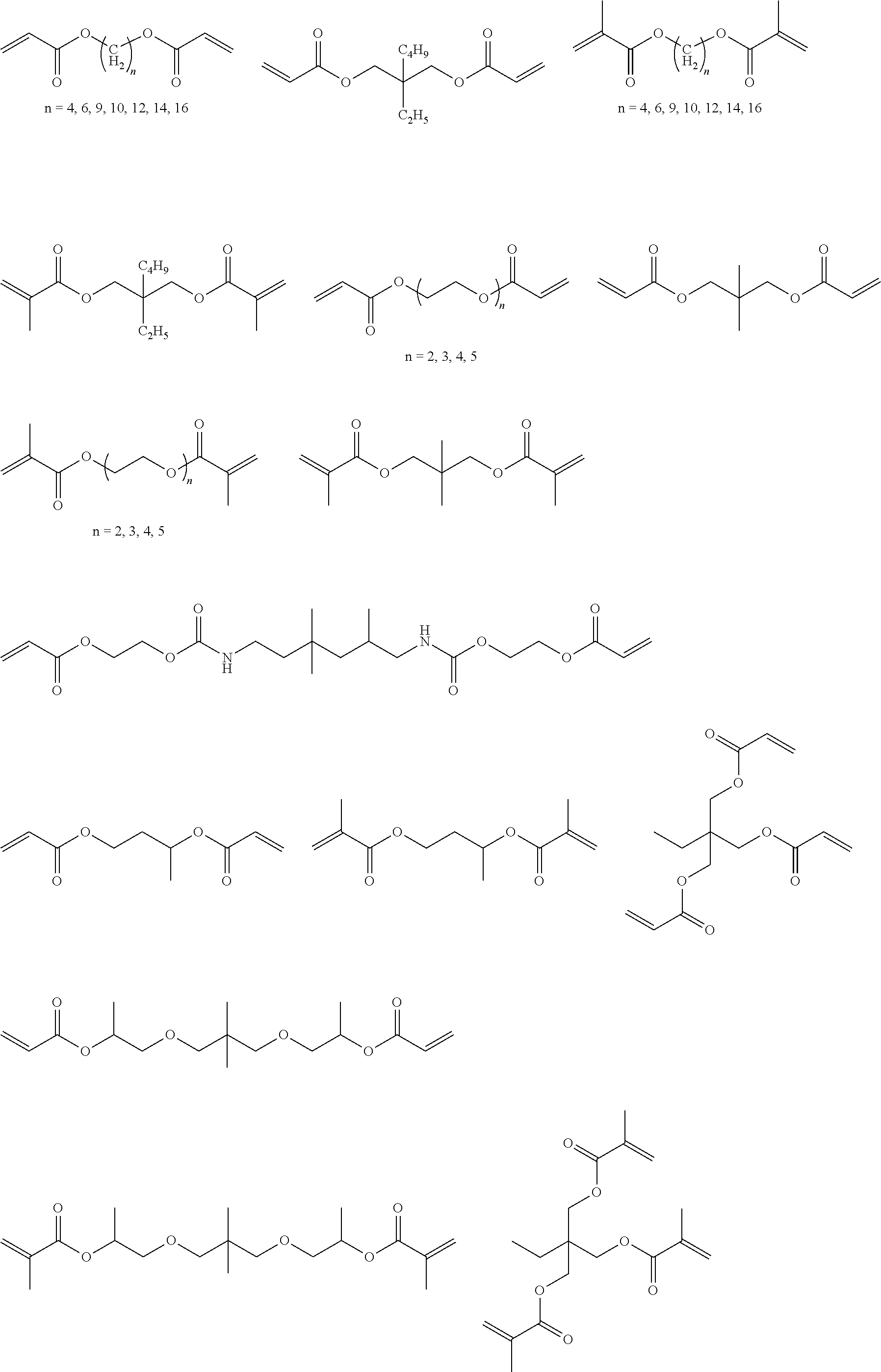

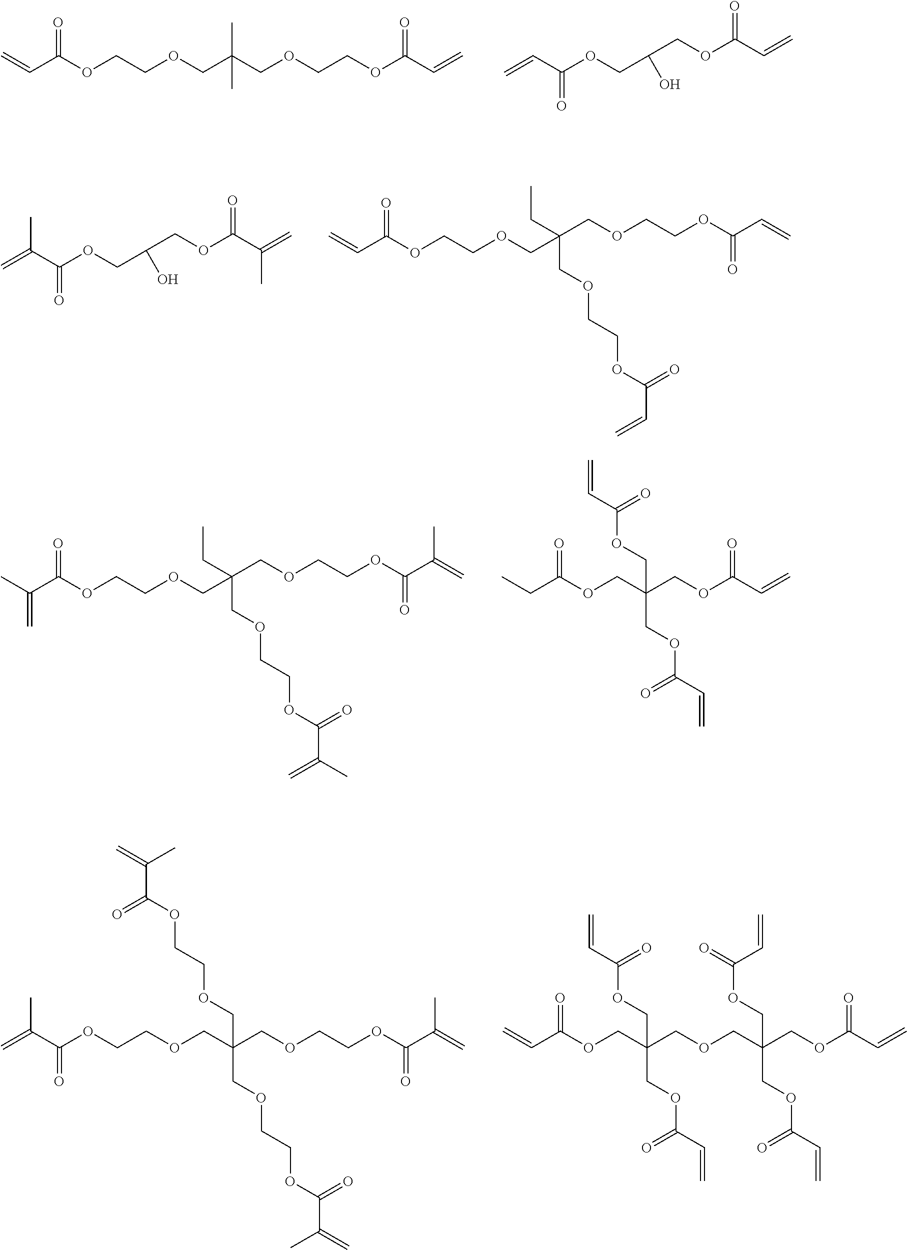

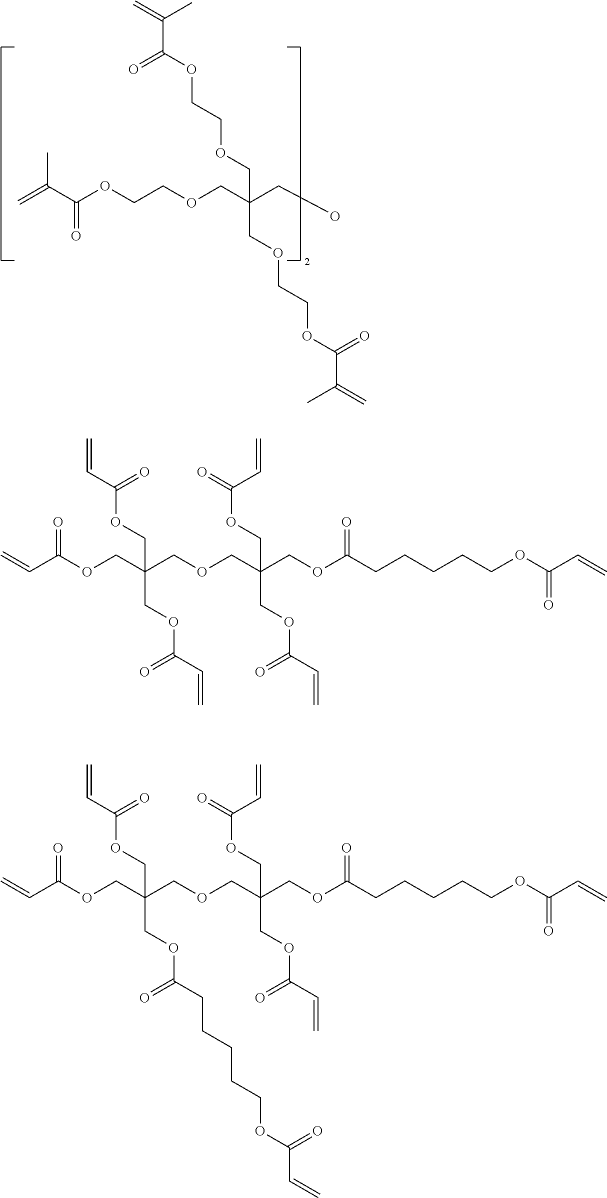

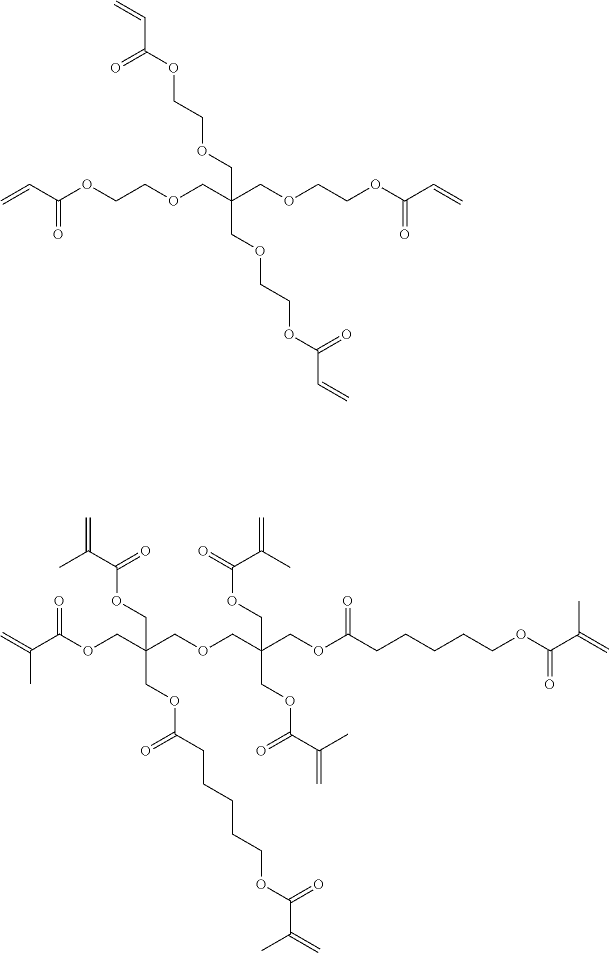

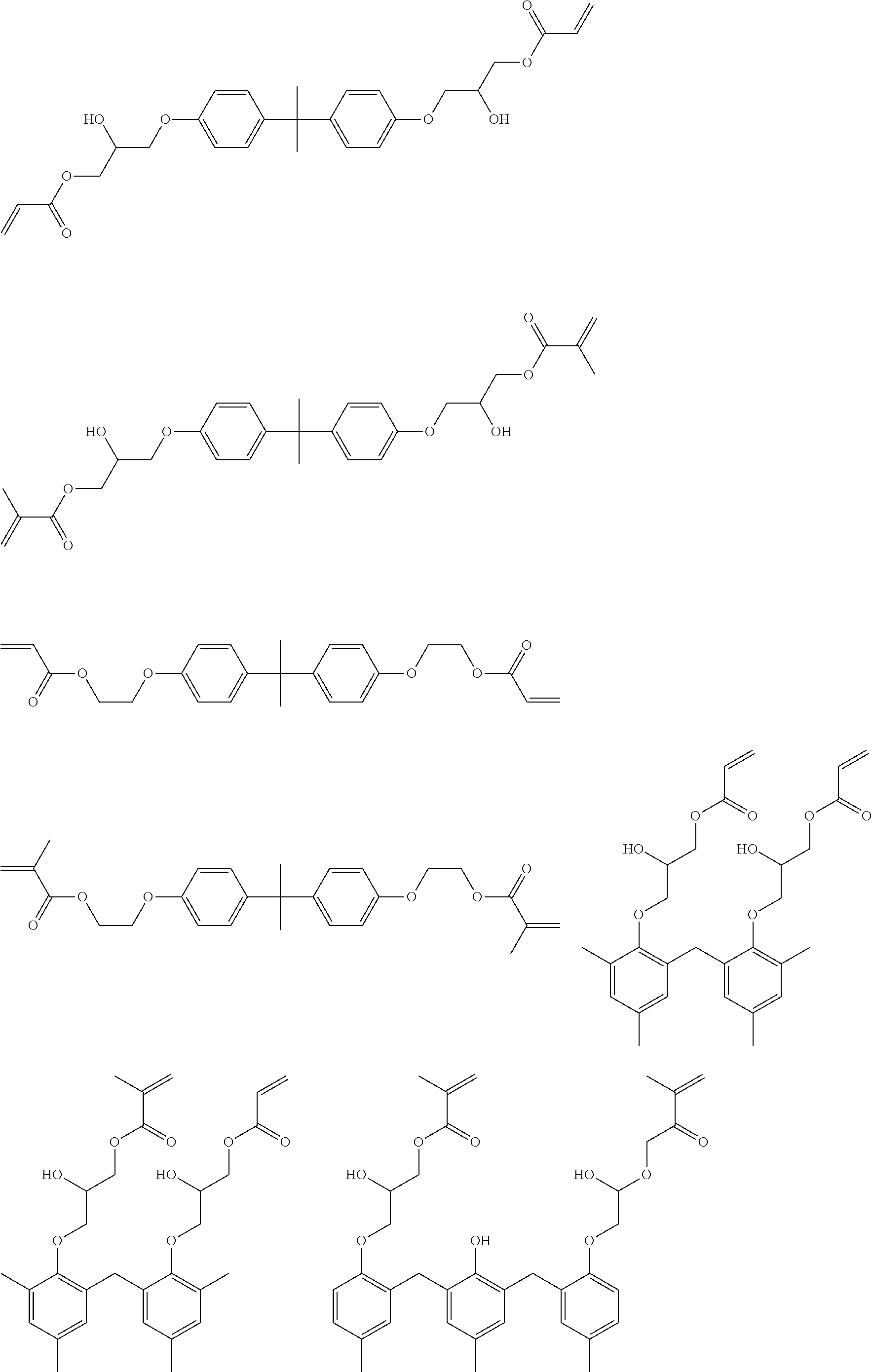

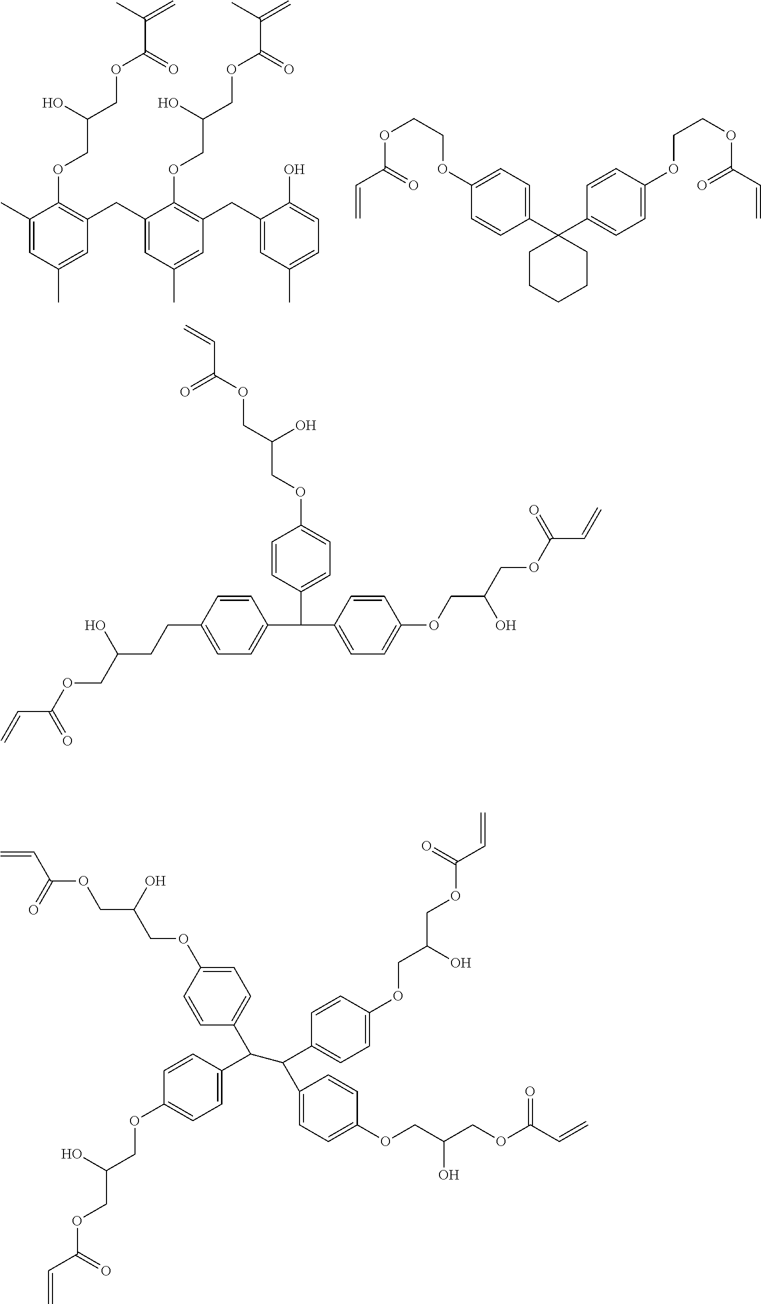

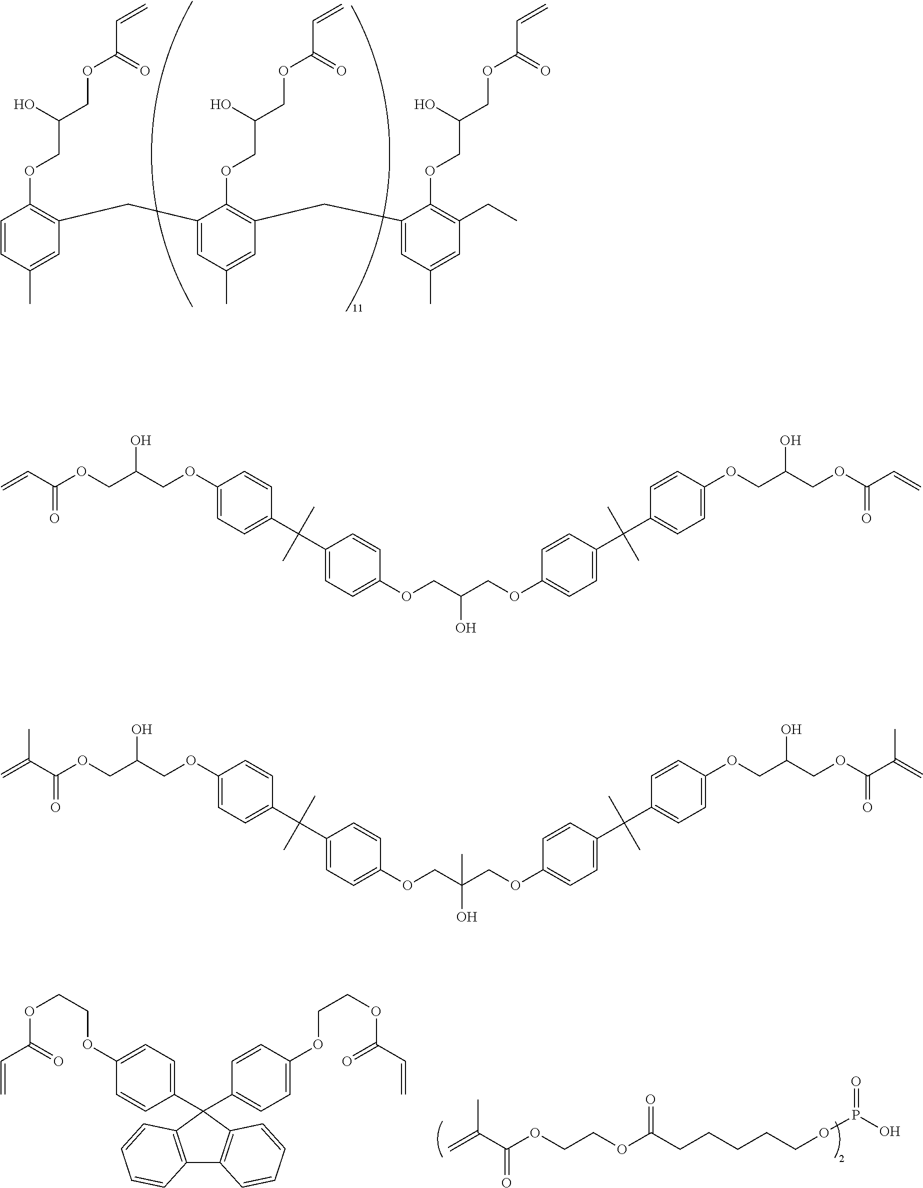

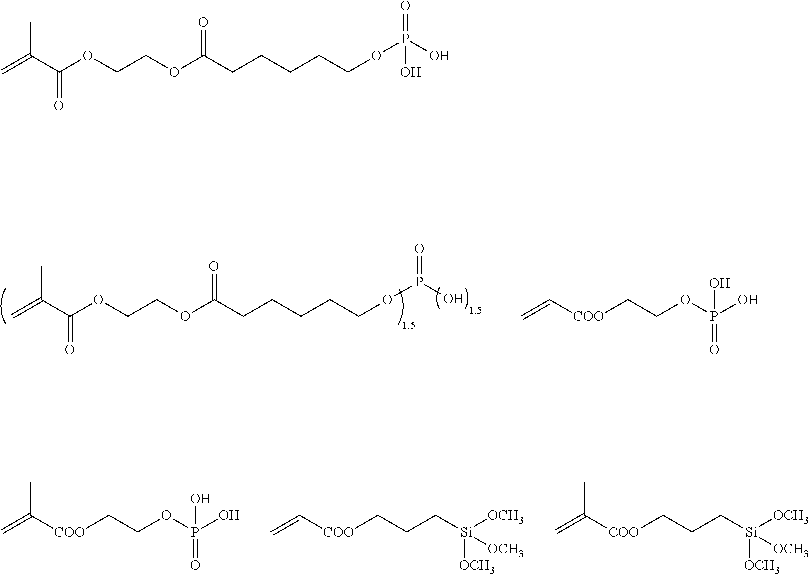

### (The Silane Coupling Agent)

In the present invention, from the perspective of imparting durability with respect to heat and humidity to the barrier laminate, a silane coupling agent is desirably added to the organic layer adjacent to the inorganic barrier layer. In particular, this effect is effectively developed when the inorganic barrier layer contains an oxide, nitride, or carbide, or some mixture thereof, that contains silicon. This is presumed to be the result of strengthening of adhesion with the inorganic barrier layer.

In the present invention, the silane coupling agent is comprised of an organic silicon compound in which both a group undergoing a hydrolysis reaction with inorganic materials and an organic functional group reacting with organic materials are contained in a single molecule, Examples of groups that undergo hydrolysis reactions with inorganic materials include alkoxy groups such as methoxy groups and ethoxy groups, acetoxy groups, and chloro groups. Examples of organic functional groups that react with organic materials include (meth)acryloyl groups, epoxy groups, vinyl groups, isocyanate groups, amino groups, and mercapto groups, A silane coupling agent having a (meth)acryloyl group is preferably employed in the present invention.

The organic silicon compound can also comprise a phenyl group or an alkyl group that does not react with either organic material or inorganic material. Mixing with a silicon compound that does not have an organic functional group, such as with an alkoxy silane that has just a hydrolyzable group, for example, is also possible. In the present invention, a single silane coupling agent, or a mixture of two or more, can be employed.

Examples of silane coupling agents that can be employed in the present invention include 3-acryloxypropyltrimethoxysilane, 3-methacryloxypropylmethyldimethoxysilane, 3-methacryloxypropyltrimethoxysilane, 2-(3,4-epoxycyclohexyl)ethyltrimethoxysilane, 3-isocyanate propyltriethoxysilane, 3-isocyanate propyltrimethoxysilane, N-(2-aminoethyl)-3-aminopropylmethyldimethoxysilane, N-(2- aminoethyl)-3-aminopropyltrimethoxysilane, 3-aminopropyltrimethoxysilane, and 3-mercaptopropylmethyldimethoxysilane.

A silane coupling agent denoted by general formula (5) below can also be preferably employed in the present invention.

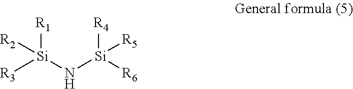

In general formula (5), each of R¹ to R⁶ denotes a substituted or unsubstituted alkyl group or aryl group, with at least one from among R¹ to R⁶ being a substituent comprising a radical polymerizable carbon-carbon double bond.

Each of R¹ to R⁵ denotes a substituted or unsubstituted alkyl group or aryl group. With the exception of when they denote substituents containing radical polymerizable carbon-carbon double bonds, R¹ to R⁶ are preferably unsubstituted alkyl groups or unsubstituted aryl groups. Alkyl groups in the form of alkyl groups having 1 to 6 carbon atoms are preferable, with methyl groups being more preferable. Aryl groups in the form of phenyl groups are preferable. Methyl groups are particularly preferable as R¹ to R⁶.

It is preferred that at least one from among R¹ to R⁶ comprises a substituent comprising a radical polymerizable carbon-carbon double bond, with two from among R¹ to R⁶ being substituents comprising radical polymerizable carbon-carbon double bonds. It is particularly preferable for one from among R¹ to R³ to comprise a substituent containing a radical polymerizable carbon-carbon double bond, and for one from among R⁴ to R⁶ to comprise a substitutent containing a radical polymerizable carbon-carbon double bond.

Two or more substituents comprising radical polymerizable carbon-carbon double bonds that are contained in the silane coupling agent denoted by general formula (5) may be identical or different, but are preferably identical.

The substituent comprising a radical polymerizable carbon-carbon double bond can be denoted by —X—Y. Here, X denotes a single-bond 1-to-6-carbon alkylene or arylene group, preferably a single-bond methylene, ethylene, propylene, or phenylene group. Y denotes a radical polymerizable carbon-carbon double-bond group, preferably an acryloyloxy group, methacryloyloxy group, acryloylamino group, methacryloylamino group, vinyl group, propenyl group, vinyloxy group, or vinylsulfonyl group, and preferably a (meth)acryloyloxy group.

R¹ to R⁶ may comprise substituents in addition to the substituents containing radical polymerizable carbon-carbon double bonds. Examples of such substituents are alkyl groups (such as methyl groups, ethyl groups, isopropyl groups, tert-butyl groups, n-octyl groups, n-decyl groups, n-hexadecyl groups, cyclopropyl groups, cyclopentyl groups, and cyclohexyl groups); aryl groups (such as phenyl groups and naphthyl groups); halogen atoms (such as fluorine, chlorine, bromine, and iodine atoms); acyl groups (such as acetyl groups, benzoyl groups, formyl groups, and pivaloyl groups); acryloxy groups (such as acetoxy groups, acryloyloxy groups, and methacryloyloxy groups); alkoxycarbonyl groups (such as methoxycarbonyl groups and ethoxycarbonyl groups); aryloxycarbonyl groups (such as phenyloxycarbonyl groups); and sulfonyl groups (such as methanesulfonyl groups and benzenesulfonyl groups).

Specific examples of the compound denoted by general formula (5) are given below. However, the present invention is not limited thereto.

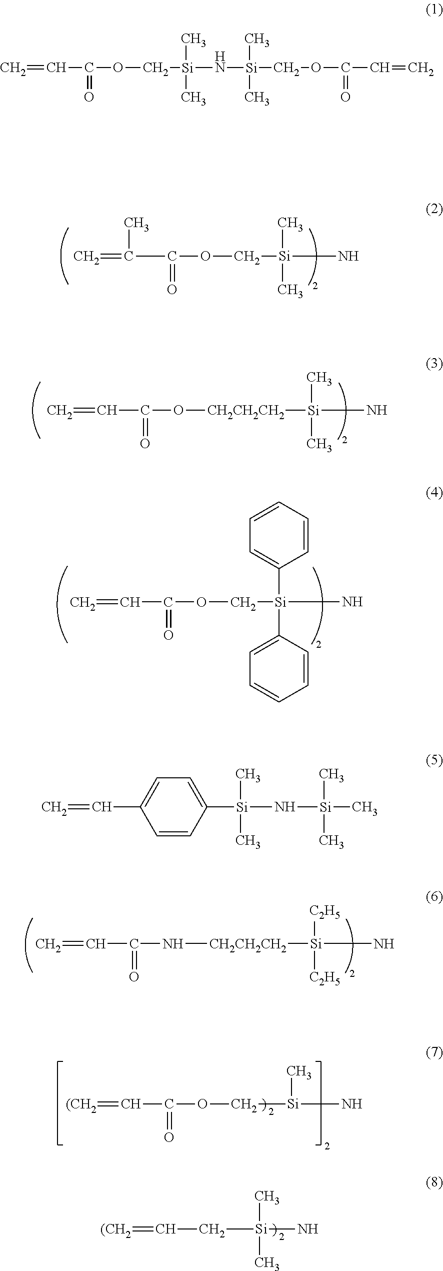

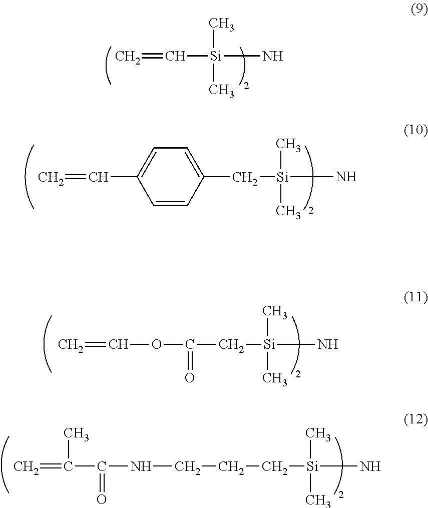

In the present invention, the quantity of silane coupling agent, as the ratio accounted for in the solid fraction (the fraction remaining once volatile components have volatized) of the polymerizable composition, is preferably 1 to 20 weight %, more preferably 2 to 10 weight %.

### (The Polymerization Initiator)

The organic layer in the present invention is usually obtained by coating and curing the polymerizable composition that comprises a polymerizable compound such as a polymerizable aromatic silane coupling agent. In the present invention, the polymerizable composition is irradiated with heat or various energy rays to induce polymerization and crosslinking, thereby forming an organic layer comprised chiefly of polymer. Examples of energy rays are UV radiation, visible light rays, infrared radiation, an electron beam, X-rays, and gamma rays. When inducing polymerization with heat, a thermopolymerization initiator is employed. When inducing polymerization with UV radiation, a photopolymerization initiator is employed, and when inducing polymerization with visible light rays, a photopolymerization initiator and sensitizing agent are employed. Of the above, a polymerizable composition containing a photopolymerization initiator is preferably polymerized and crosslinked with UV radiation.

When employing a photopolymerization initiator, the quantity is preferably 0.1 mol % or more of the total quantity of polymerizable compound, more preferably 0.5 to 2 mol %. Employing such a composition suitably controls the polymerization reaction taking place via reactions producing active components. Examples of photopolymerization initiators include the Irgacure series commercially available from Ciba Specialty Chemicals (such as Irgacure 651, Irgacure 754, Irgacure 184, Irgacure 2959, Irgacure 907, Irgacure 369, Irgacure 379, and Irgacure 819); the Darocure series (such as Darocure TPO and Darocure 1173); Quantacure PDO; and the Ezacure series commercially available from Sartomer Corportion (such as Ezacure TZM and Ezacure TZT).

### (The Method of Forming the Organic Layer)

The organic layer can be formed by forming a thin film of the polymerizable composition by solution coating or vacuum deposition, and then inducing polymerization by irradiation with energy rays. Examples of the solution coating method include the dip coating, air knife coating, curtain coating, roller coating, wire bar coating, gravure coating, or slide coating method. An alternative example is the extrusion coating method employing a hopper described in U.S. Pat. No. 2,681,294. An example of a vacuum deposition method is the flash vapor deposition method,

Examples of polymerization methods include irradiation with light and irradiation with an electron beam. The method of irradiation with light is preferable. Among methods of irradiation with light, the method of irradiation with UV radiation is preferred. In the method of irradiation with UV radiation, UV radiation is normally irradiated by a high-pressure mercury lamp or low-pressure mercury lamp. The irradiation energy is preferably 0.2 J/cm² or higher, more preferably 0.6 /cm² or higher. The curing reaction of the polymerizable composition is impeded by oxygen in the air, it is thus preferable to reduce the oxygen concentration or oxygen partial pressure during polymerization. When reducing the oxygen concentration during polymerization by the nitrogen replacement method, the oxygen concentration is preferably reduced to 2% or less, more preferably 0.5% or less, When reducing the oxygen partial pressure during polymerization by the pressure reduction method, the total pressure is preferably 1,000 Pa or less, more preferably 100 Pa or less. Also, it is preferable to conduct UV radiation polymerization by irradiating energy of 1 J/cm² or higher under reduced pressure conditions of 100 Pa or less.

The organic layer in the present invention is preferably smooth with high film hardness. The absence of foreign matter such as particles and protrusions on the surface of the organic layer is required. Thus, formation of the organic layer in a clean room is desirable. The cleanliness class is preferably 10,000 or less, more preferably 1,000 or less. The smoothness of the organic layer is preferably less than 10 nm, more preferably less than 0.52 nm, as the average roughness (Ra value) of a 1 μm square. The polymerization rate of the monomer is preferably 85% or more, more preferably 88% or more, further preferably 90% or more, and still further preferably, 92% or more. The polymerization rate referred to here means the ratio of the polymerizable groups that have reacted among all the polymerizable groups in the monomer mixture. The polymerization rate can be quantified by the infrared radiation absorption method.

The refractive index of the organic layer is 1.60 or higher. There is no specific upper limit; but way of example, it can be 1.7 or lower. It is preferably lower than the refractive index of the adjacent inorganic barrier layer. The difference with the refractive index of the adjacent inorganic barrier layer preferably falls within a range of 0 to 0.35, more preferably within a range of 0 to 0.1. By employing a refractive index of 1.60 or higher, a barrier properties-enhancing effect is achieved. By keeping the difference with the refractive index of the inorganic barrier layer within the above range, a haze value-reducing effect is achieved.

The thickness of the organic layer is not specifically limited. However, when excessively thin, it becomes difficult to achieve a film of uniform thickness. When excessively thick, cracks are generated by external forces, compromising the barrier properties. From these perspectives, the thickness of the organic layer is preferably 50 to 5,000 nm, more preferably 500 to 2,500 nm.

A hard organic layer is desirable. It has been found that, when the degree of hardness of the organic layer is high, the inorganic barrier layer forms smoothly, and as a result barrier properties can be enhanced. The hardness of the organic layer can be denoted as a microhardness by the nanoindentation method. The microhardness of the organic layer is preferably 150 N/mm or more, more preferably 180 N/mm or more, and further preferably, 200 N/mm or more.

### (The Inorganic Barrier Layer)

The inorganic barrier layer is normally a thin layer comprised of a metal oxide. The inorganic barrier layer in the present invention has a refractive index of 1.60 or more, preferably 1.8 to 2. Any method can be used to form the inorganic barrier layer so long as it permits the formation of the targeted thin film. Examples include physical vapor deposition methods (PVDs) such as the vapor deposition method, the sputtering method, and the ion plating method; various chemical vapor deposition methods (CVDs); and liquid phase deposition methods such as the plating and sol-gel methods. In particular, CVD methods and the sputtering method are preferable because they permit the formation of an inorganic barrier layer that is dense and affords high barrier properties. The composition of the inorganic barrier layer of the present invention is preferably an oxide, nitride, carbide, or a mixture thereof, containing silicon and/or aluminum, and more preferably an oxide, nitride, carbide, or a mixture thereof, containing silicon. Other metal oxides, metal nitrides, or metal carbides can be employed in combination. The inorganic barrier layer in the present invention preferably essentially consists of an oxide, nitride, carbide, or a mixture thereof, containing silicon and/or aluminum, “Essentially” means that other inorganic materials are not actively added. For example, 98 weight % of the total weight of the inorganic barrier layer is comprised of these compounds.

For example, an oxide, nitride, carbide, oxynitride, oxynitrocarbide, or the like containing one or more metals selected from among Al, In, Sn, Zn, Ti, Cu, Ce, and Ta, can be preferably employed in combination as an additional metal oxide or the like. Of these oxides, nitrides, and oxynitrides of metals selected from among Al, In, Sn, Zn, and Ti are preferable. Al metal oxides, nitrides, or oxynitrides is particularly preferred. The inorganic barrier layer can contain other elements as secondary components. The smoothness of the inorganic barrier layer that is formed by the present invention is preferably less than 1 nm and more preferably 0.5 nm or less as a 1 μm square average roughness (Ra value). Thus, the inorganic barrier layer is preferably formed in a clean room. The degree of cleanliness is preferably class 10,000 or less, more preferably class 1,000 or less.

The thickness of a single layer in the inorganic barrier layer is preferably 15 to 100 nm, more preferably 20 to 50 nm. From the perspective of enhancing barrier properties, a thick inorganic barrier layer is qualitatively advantageous. However, the productivity of the inorganic barrier layer forming step tends to deteriorate in roughly inverse proportion to the thickness of the inorganic barrier layer. Since the productivity of the inorganic barrier layer manufacturing step is a controlling factor in the production cost of the barrier film, employing a thick inorganic barrier layer directly increases the cost. When the thickness of the inorganic barrier layer exceeds 100 nm, the risk of generating defects in the form of cracks in the inorganic barrier layer tends to increase when the barrier film bends. Additionally, when the inorganic barrier layer is made thinner than what is stated above, the probability of generating pinholes during formation of the inorganic barrier layer increases and the barrier properties tend to deteriorate greatly.

### (Laminating the Organic Layer and the Inorganic Barrier Layer)

The organic layer and the inorganic barrier layer can be laminated by sequentially and repeatedly forming organic and inorganic films based on a desired layer structure.

### (Functional Layers)

The device of the present invention can include functional layers on the barrier laminate or in other positions. Functional layers are described in detail in paragraphs [0036] to [0038] in Japanese Unexamined Patent Publication (KOKAI) No, 2006-289627. Examples of additional functional layers include matting agent layers, protective layers, antistatic layers, smoothing layers, adhesion-enhancing layers, light-blocking layers, antireflective layers, hardcoat layers, stress-alleviating layers, anti-haze layers, antifouling layers, layers to be printed, and adhesive layers.

### Applications of the Barrier Laminate

The barrier laminate of the present invention is normally provided on a support. A variety of applications are made possible by means of the support selected. In addition to substrate films, supports include various devices and optical elements. Specifically, the barrier laminate of the present invention can be employed as the barrier layer of a gas barrier film. The barrier laminate and gas barrier film of the present invention can be used to seal devices that require barrier properties. The barrier laminate and gas barrier film of the present invention can be applied to optical elements. These will be described in detail below.

### <Gas Barrier Films>

A gas barrier film comprises a substrate film and a barrier laminate formed on the substrate film. In a gas barrier film, the barrier laminate of the present invention can be provided on just one side of the substrate film, or on both sides thereof. The barrier laminate of the present invention can be laminated, from the substrate film side, in the order of the inorganic barrier layer and the organic layer, or in the order of the organic layer and the inorganic barrier layer. The topmost layer in the laminate of the present invention can be either the inorganic barrier layer or the organic layer.

The gas barrier film in the present invention is a film substrate having a barrier layer that functions to block out atmospheric oxygen, moisture, nitrogen oxides, sulfur oxides, ozone, and the like.

The gas barrier film can also comprise structural components in addition to the barrier laminate and substrate film (such as functional films such as adhesive layers). The functional films can be positioned on the barrier laminate, between the barrier laminate and the substrate film, or on the side of the substrate film (back surface) on which the barrier laminate is not provided.

### (Plastic Films)

In the gas barrier film of the present invention, a plastic film is normally employed as the substrate film. The material, thickness, and the like of the plastic film that is employed are not specifically limited so long as the film is capable of holding a laminate of an organic layer, an inorganic barrier layer, and the like. They can be suitably selected based on the targeted use. The plastic film material described in paragraphs [0027] to [0036] in Japanese Unexamined Patent Publication (KOKAI) No. 2011-102042 is preferably employed.

The thickness of the plastic film employed in the gas barrier film of the present invention can be suitably selected based on the application and is not specifically limited. Typically, it will be 1 to 800 μm, preferably 10 to 200 μm. These plastic films can have functional layers such as transparent electrically conductive layers and primer layers. Functional layers are described in detail in paragraphs [0036] to [0038] in Japanese Unexamined Patent Publication (KOKAI) No. 2006-289627. Examples of additional functional layers are matting agent layers, protective layers, antistatic layers, smoothing layers, adhesion-enhancing layers, light-blocking layers, antireflective layers, hardcoat layers, stress-alleviating layers, anti-haze layers, antifouling layers, layers to be printed, and adhesive layers.

The barrier laminate and/or gas barrier film of the present invention can achieve a water vapor permeability of 1×10⁻⁴ g/m²/day or less in the case of a single stack consisting of an organic layer and an inorganic layer when the atmospheric conditions on the water vapor supply side are 40° C. with a relative humidity of 90%. Two stacks can achieve a water vapor permeability of 2×10⁻⁵ g/m²/day or less.

### <The Device>

The barrier laminate and gas barrier film of the present invention are preferably employed in devices the functions of which deteriorate due to chemical components (oxygen, water, nitrogen oxides, sulfur oxides, ozone, and the like) in the air. Examples of such devices include organic EL elements, liquid-crystal display elements, thin-film transistors, touch panels, electronic paper, solar cells, and other electronic devices. The harrier laminate and gas barrier film of the present invention are preferably employed in organic EL elements.

The barrier laminate of the present invention can also be employed in the sealing of devices with films. This is a method in which the device itself functions as a support, and the barrier laminate of the present invention is provided on the surface thereof. The device can be covered with a protective layer prior to applying the barrier laminate.

The gas barrier film of the present invention can also be employed as a device substrate or as a film for sealing by the solid sealing method. The “solid sealing method” is a method of forming a protective layer on a device and then stacking and curing an adhesive layer and gas barrier film thereover. The adhesive is not specifically limited. Examples if the adhesive include thermosetting epoxy resins and photosetting acrylate resins.

### (Organic EL Elements)

An example of an organic EL element employing a gas barrier film is described in detail in Japanese Unexamined Patent Publication (KOKAI) No. 2007-30387.

### (Liquid-Crystal Display Elements)

A reflective type liquid-crystal display device has a configuration that is sequentially comprised of, from the bottom up, a substrate, reflective electrode, lower orientation film, liquid-crystal layer, upper orientation film, transparent electrode, upper substrate, λ/4 plate, and polarizing film, The gas barrier film of the present invention can be employed as the transparent electrode substrate and upper substrate, In the case of a color display, a color filter layer is further preferably disposed between the reflective electrode and lower orientation film, or between the upper orientation film and transparent electrode. A transparent liquid-crystal display device has a configuration that is sequentially comprised of, from the bottom up, a backlight, polarizer, λ/4 plate, lower transparent electrode, lower orientation layer, liquid-crystal layer, upper orientation layer, upper transparent electrode, upper substrate, λ/4 plate, and polarizing film. Therein, the substrate of the present invention can be employed as the upper transparent electrode and the upper substrate. In the case of a color display, a color filter layer is further preferably disposed between the lower transparent electrode and the lower orientation film, or between the upper orientation film and the transparent electrode. Although not specifically limited, the type of liquid-crystal cell is preferably of the TN (twisted nematic), STN (super twisted nematic), HAN (hybrid aligned nematic), VA (vertical alignment), ECB (electrically controlled birefringence), OCB (optically compensated bend), or CPA (continuous pinwheel alignment) type, or IPS (in-plane switching).

### (Other)

Examples of other applications include the thin-film transistor described in Japanese Translated PCT Patent Application Publication (TOKUHYO) Heisei No. 10-512104; the touch panel described in publications such as Japanese Unexamined Patent Publication (KOKAI) Nos. Heisei 5-127822 and 2002-48913; the electronic paper described in Japanese Unexamined Patent Publication (KOKAI) No. 2000-98326; and solar cell described in Japanese Unexamined Patent Publication (KO 1) No. (Heisei)07-160334.

### <Optical Elements>

A circular polarizer is an example of an optical component employing the gas barrier film of the present invention.

### (Circular Polarizers)

The gas barrier film of the present invention can be employed as a substrate and laminated with a λ/4 plate and a polarizer to fabricate a circular polarizer. In that case, the lamination is conducted so that the slow axis of the λ/4 plate forms an angle of 45° with the absorption axis of the polarizer. For such a polarizer, a polarizer formed by extension in a direction forming an angle of 45° with the longitudinal direction can be preferably employed. By way of example, the polarizer described in Japanese Unexamined Patent Publication (KOKAI) No. 2002-865554 can be preferably employed.

### EXAMPLES

The present invention will be described in greater detail below through examples. The materials, amounts used, ratios, processing contents, and processing procedures indicated in the embodiments given below can be suitably modified without departing from the spirit or scope of the present invention, Accordingly, the scope of the present invention is not limited to the specific examples given below.

### (Synthesis of Polymerizable Compound (AC44))

A 4.25 g of 4,4′-[1-[4-[1-(4-hydroxyphenyl)-1-methylethyl]phenyl]ethylidene]-bisphenol, 3.34 g of triethylamine, and 7 g of tetrahydrofuran were combined and cooled to 0° C. Subsequently, acrylic acid chloride (2.99 g) was added dropwise and the mixture was stirred for 1 hour at a reaction temperature of 0° C. followed by stirring for 3 hours at 25° C. The reaction mixture was diluted by adding ethyl acetate (50 mL). It was then washed twice with water (50 mL), once with saturated sodium bicarbonate solution (80 mL), once with water (50 mL), and once with saturated brine, in this order. The organic layer was separated, dried with anhydrous magnesium sulfate, and filtered. The solvent was distilled out under reduced pressure from the filtrate obtained, yielding the targeted polymerizable compound (AC44) (72.1 g) in the form of an ethyl acetate solution. The ¹H-NMR measurement results of the product are given below.

### ¹H-NMR Data

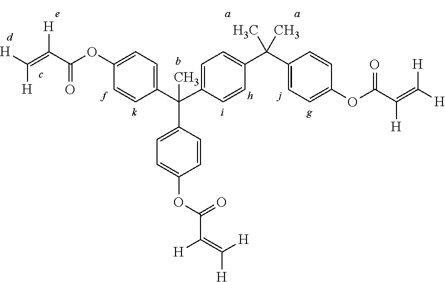 [SMILES: C=CC(=O)Oc1ccc(C(C)(C)c2ccc(C(C)(c3ccc(OC(=O)C=C)cc3)c3ccc(OC(=O)C=C)cc3)cc2)cc1]

| δ (ppm) | Signal form | No. of protons | Assignment |
|---|---|---|---|
| 1.68 | s | 6 | a |
| 2.18 | s | 3 | b |
| 5.98-6.01 | m | 3 | c |
| 6.27-6.34 | m | 3 | d |
| 6.56-6.61 | m | 3 | e |
| 6.97-7.04 | m | 10 | f, g, h, i |
| 7.09-7.13 | m | 6 | j, k |

### (Synthesis of Compound 1)

Compound 1 was synthesized as follows. First, in the presence of sodium hydroxide, anthrone compound (1-1) below (X and Y denote hydrogen atoms) and epichlorohydrin were heated to 65° C. in methanol solvent to synthesize oxyanthracene compound (1-2) (X and Y denote hydrogen atoms). Next, this compound was dimerized by irradiation with the light of a metal halide lamp (center wavelength 365 nm) at 10° C. to synthesize the diglycidyloxy compound having an anthracene skeleton of (1-3) below (X¹, X², Y¹, and Y² denote hydrogen atoms). Finally, in the solvent propylene glycol monomethyl ether acetate, this compound was reacted with acrylic acid over a temperature range of 90 to 120° C. in the presence of 500 ppm of hydroquinone as a polymerization inhibitor to introduce an acrylic group, resulting in the synthesis of compound 1.

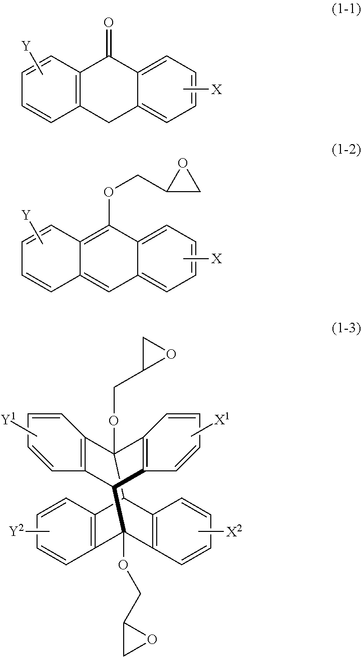

### (Synthesis of Compound 2)

Compound 2 was synthesized as follows, First, the bisphenyl phenol fluorene compound the formula of which is given below in which R is a hydrogen atom was subjected to the action of epichlorohydrin, Next, the bisphenyl phenol fluorene epoxy compound indicated below (where X denotes the above bisphenyl phenol fluorene compound) was synthesized. This was then reacted with acrylic acid to synthesize compound 2 in the form of bisphenyl phenol fluorene type expoxy acrylate resin. The reaction of the bisphenyl phenol fluorene compound and epichlorohydrin was conducted over a temperature range of 50 to 120° C. The reaction with acrylic acid was conducted in a solvent in the form of propylene glycol monomethyl ether acetate over a temperature range of 90 to 120° C. in the presence of 500 ppm of hydroquinone as a polymerization inhibitor.

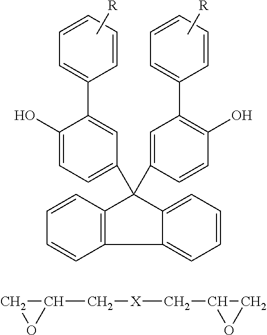

### (Synthesis of Compound 4)

Compound 4 was synthesized by dissolving the epoxy compound, the formula of which is given below and both ends of which had been glycidyl etherified, in a solvent in the form of Cellosolve acetate; and subjecting the solution to a reaction with acrylic acid at 110 to 120° C. by using 2-ethyl-4-imidazole as catalyst in the presence of 500 ppm of methylhydroquinone as a polymerization inhibitor.

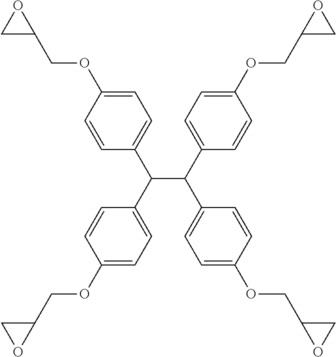 [SMILES: c1cc(C(c2ccc(OCC3CO3)cc2)C(c2ccc(OCC3CO3)cc2)c2ccc(OCC3CO3)cc2)ccc1OCC1CO1]

### Example 1

### Fabrication of Gas Barrier Films

The organic layers and inorganic barrier layers indicated below were alternately laminated in that order on polyethylene terephthalate films (manufactured by Toyobo Co., Cosmoshine A4300, thickness 100 μm) to fabricate gas barrier films. As indicated in the table below, gas barrier films were fabricated in the two forms of a single stack product of one laminate set of an organic layer and an inorganic layer, and a two stack product of two laminate sets.

### (Formation of the Organic Layer)

Polymerizable compositions with solid fraction concentrations of 15 weight %, comprising a solid fraction in the form of a polymerizable compound, a silane coupling agent as needed (KBM5105 manufactured by Shin-Etsu Chemical Co., Ltd. or the silane coupling agent (1) indicated below), and a polymerization initiator (Esacure KT046, manufactured by Lamberti Corp.) in the compositions indicated in the table below were fabricated using 2-butanone as solvent. The compositions were applied in quantities calculated to yield a film thickness of 1.5 μm, irradiated with UV radiation with a primary wavelength of 365 nm at an irradiation level of 0.6 J/cm² in a nitrogen atmosphere with an oxygen content of 100 ppm or less, and cured by photopolymerization to fabricate organic layers.

The refractive index of the organic layer following film formation was determined by measuring the reflection amplitude ratio angle and the phase differential of the polarized light between the incident waves and reflected waves of a sample on which an organic layer had been fabricated by the above method on an Si wafer of 100 mm in diameter with a spectral ellipsometer M-200U manufactured by J. A. Woollam Corp. of the U.S., and performing analysis with the database of the same device.

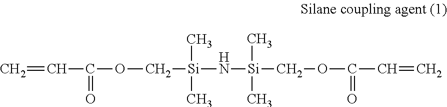 [SMILES: C=CC(=O)OC[Si](C)(C)N[Si](C)(C)COC(=O)C=C]

### (Forming the Inorganic Barrier Layer)

A silicon nitride film (refractive index 1.95) of 35 nm in thickness was formed on the surface of the organic layer fabricated above by the plasma CVD method employing ammonia, silane, and hydrogen as starting gases.

TABLE 1

| | Solid fraction composition | | | | Refractive |
|---|---|---|---|---|---|
| | | | Silane | | index |
| | Polymerizable | Polymerizable | coupling | Polymerization | following film |
| | compound 1 | compound 2 | agent | initiator | formation |
| A (Comparative | None | Compound 3 | None | 4 wt % | 1.52 |
| Example) | | 96 wt % | | | |
| B (Comparative | None | Compound 4 | None | 4 wt % | 1.585 |
| Example) | | 96 wt % | | | |
| C (Comparative | AC44 | Compound 4 | None | 4 wt % | 1.594 |
| Example) | 48 wt % | 48 wt % | | | |
| D (Present | AC44 | None | None | 4 wt % | 1.605 |
| invention) | 96 wt % | | | | |
| E (Present | Compound 1 | None | None | 4 wt % | 1.629 |
| invention) | 96 wt % | | | | |
| F (Present | Compound 2 | None | None | 4 wt % | 1.635 |
| invention) | 96 wt % | | | | |
| G (Comparative | None | Compound 4 | KBM-5103 | 4 wt % | 1.581 |
| Example) | | 90 wt % | 6 wt % | | |
| H (Present | AC44 | None | KBM-5103 | 4 wt % | 1.601 |
| invention) | 90 wt % | | 6 wt % | | |
| I (Present | AC44 | None | Silane coupling | 4 wt % | 1.601 |
| invention) | 90 wt % | | agent (1) | | |
| | | | 6 wt % | | |

In the table, compound 3 is the following compound (Aronix M-309, manufactured by Toa Gosei (Ltd.)).

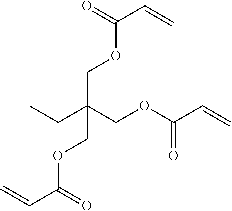 [SMILES: C=CC(=O)OCC(CC)(COC(=O)C=C)COC(=O)C=C]

### (Evaluation of Performance of Gas Barrier Films)

The transparence (haze), barrier properties (water vapor permeability), and heat and humidity durability (barrier properties over time with heat and humidity) of the gas barrier films obtained were evaluated by the following methods.

### [Evaluation of Transparence]

Transparence was evaluated as the haze value using a Hazemeter Hz-1 manufactured by Suga Test Instruments Co., Ltd. in accordance with JIS-K7105. The lower the haze value, the better the transparence.

### [Evaluation of Barrier Properties]

The water vapor permeability (g/m²/day) was evaluated by measurement by the method described by G. Nisato, P. C. P. Bouten, P. J. Slikkerveer, et al., SID Conference Record of the international Display Research Conference, pp. 1435-1438. The atmosphere on the water vapor supply side was 40° C. with 90% relative humidity.

### [Evaluation of Heat and Humidity Durability]

The gas barrier films that had been fabricated were placed for 2,000 hours in an 85° C., 85% RH atmosphere. The barrier properties were then evaluated by the same method as that employed in the [Evaluation of barrier properties] above. The lower the amount of the increase in the water vapor permeability over time, the better the heat and humidity durability.

The results are given in the following table.

TABLE 2

| | | Organic layer | | | | Water | Water vapor |
|---|---|---|---|---|---|---|---|
| | | | Refractive | Silane | Haze | vapor | permeability |
| | Form of | Formula | index | coupling | value | permeability | following heat |
| Gas barrier film | lamination | No. | λ: 550 nm | agent | (%) | over time | and humidity |
| 101 (Comparative Example) | 1 stack | A | 1.520 | None | 1.7 | 3.4 × 10⁻⁴ | 6.6 × 10⁻⁴ |
| 102 Comparative Example | 1 stack | B | 1.585 | None | 1.6 | 1.2 × 10⁻⁴ | 2.4 × 10⁻⁴ |
| 103 (Comparative Example) | 1 stack | C | 1.594 | None | 1.6 | 1.2 × 10⁻⁴ | 2.3 × 10⁻⁴ |
| 104 (Present invention) | 1 stack | D | 1.605 | None | 1.1 | 5.8 × 10⁻⁵ | 1.1 × 10⁻⁴ |
| 105 (Present invention) | 1 stack | E | 1.629 | None | 1.0 | 5.5 × 10⁻⁵ | 1.0 × 10⁻⁴ |
| 106 (Present invention) | 1 stack | F | 1.635 | None | 1.0 | 6.9 × 10⁻⁵ | 1.3 × 10⁻⁴ |
| 107 (Comparative Example) | 1 stack | G | 1.581 | KBM-5103 | 1.6 | 1.2 × 10⁻⁴ | 2.3 × 10⁻⁴ |
| | | | | 6 wt % | | | |
| 108 (Present invention) | 1 stack | H | 1.601 | KBM-5103 | 1.1 | 6.6 × 10⁻⁵ | 8.9 × 10⁻⁵ |
| | | | | 6 wt % | | | |
| 109 (Present invention) | 1 stack | I | 1.601 | Silane | 1.1 | 6.5 × 10⁻⁵ | 8.5 × 10⁻⁵ |
| | | | | coupling | | | |
| | | | | agent (1) | | | |
| | | | | 6 wt % | | | |
| 201 (Comparative Example) | 2 stacks | A | 1.520 | None | 2.6 | 1.1 × 10⁻⁴ | 2.1 × 10⁻⁴ |
| 202 (Comparative Example) | 2 stacks | B | 1.585 | None | 2.3 | 2.9 × 10⁻⁵ | 5.4 × 10⁻⁵ |
| 203 (Comparative Example) | 2 stacks | C | 1.594 | None | 9.2 | 2.8 × 10⁻⁵ | 5.0 × 10⁻⁵ |
| 204 (Present invention) | 2 stacks | D | 1.605 | None | 1.4 | 1.2 × 10⁻⁵ | 2.0 × 10⁻⁵ |
| 205 (Present invention) | 2 stacks | E | 1.629 | None | 1.2 | 1.4 × 10⁻⁵ | 2.2 × 10⁻⁵ |
| 206 (Present invention) | 2 stacks | F | 1.635 | None | 1.1 | 1.6 × 10⁻⁵ | 2.5 × 10⁻⁵ |
| 207 (Comparative Example) | 2 stacks | G | 1.581 | KBM-5103 | 2.4 | 7.7 × 10⁻⁵ | 1.3 × 10⁻⁴ |
| | | | | 6 wt % | | | |
| 208 (Present invention) | 2 stacks | H | 1.601 | KBM-5103 | 1.5 | 1.3 × 10⁻⁵ | 1.7 × 10⁻⁵ |
| | | | | 6 wt % | | | |
| 209 (Present invention) | 2 stacks | I | 1.601 | Silane | 1.5 | 1.2 × 10⁻⁵ | 1.5 × 10⁻⁵ |
| | | | | coupling | | | |
| | | | | agent (1) | | | |
| | | | | 6wt % | | | |

As will be clear from the above results, the gas barrier film employing an organic layer of the present invention exhibited a low haze value and good transparence, as well as high barrier properties. Further, the use of a suitable quantity of silane coupling agent in the organic layer in the present invention was found to greatly improve the heat and humidity durability relative to the comparative examples. The barrier property of a single stack product of the organic layer/inorganic layer of the present invention achieved a water vapor permeability of less than 1×10⁻⁴ g/m²/day, making it possible to fabricate a barrier film substrate with a water vapor permeability of 1×10⁻⁴ g/m²/day with a low number of stacks and at low cost.

### Example 2

Gas barrier films in which the material and thickness of the inorganic barrier film were varied as shown in Table 3 were fabricated from samples 102 and 104 in Example 1 and the barrier properties (water vapor permeability) were evaluated. Films of silicon nitride were formed by the plasma CVD method that was used in Example 1, films of aluminum oxide (refractive index 1.63) were formed by the sputtering method, and films of silicon oxide (refractive index 1.45) were formed by the electron beam vapor deposition method.

TABLE 3

| | Organic layer | | Inorganic barrier layer | | | |
|---|---|---|---|---|---|---|
| | Formula | Refractive | | Refractive | Thickness | Water vapor |
| Gas barrier film | no. | index | Material | index | (nm) | permeability |
| 401 (Comparative Example) | B | 1.585 | Silicon nitride | 1.95 | 13 | 1.1 × 10⁻³ |
| 402 (Comparative Example) | B | 1.585 | Aluminum oxide | 1.63 | 13 | 1.4 × 10⁻³ |
| 403 (Comparative Example) | B | 1.585 | Silicon oxide | 1.45 | 13 | 2.7 × 10⁻³ |
| 404 (Present invention) | D | 1.605 | Silicon nitride | 1.95 | 13 | 7.5 × 10⁻⁴ |
| 405 (Present invention) | D | 1.605 | Aluminum oxide | 1.63 | 13 | 9.3 × 10⁻⁴ |
| 406 (Comparative Example) | D | 1.605 | Silicon oxide | 1.45 | 13 | 1.9 × 10⁻³ |
| 407 (Comparative Example) | B | 1.585 | Silicon nitride | 1.95 | 35 | 1.2 × 10⁻⁴ |
| 408 (Comparative Example | B | 1.585 | Aluminum oxide | 1.63 | 35 | 1.5 × 10⁻⁴ |
| 409 (Comparative Example) | B | 1.585 | Silicon oxide | 1.45 | 35 | 2.9 × 10⁻⁴ |
| 410 present invention | D | 1.605 | Silicon nitride | 1.95 | 35 | 5.8 × 10⁻⁵ |
| 411 present invention) | D | 1.605 | Aluminum oxide | 1.63 | 35 | 7.0 × 10⁻⁵ |
| 412 Comparative Example) | D | 1.605 | Silicon oxide | 1.45 | 35 | 1.4 × 10⁻⁴ |
| 413 Comparative Example) | B | 1.585 | Silicon nitride | 1.95 | 90 | 4.6 × 10⁻⁵ |
| 414 Comparative Example) | B | 1.585 | Aluminum oxide | 1.63 | 90 | 5.7 × 10⁻⁵ |
| 415 (Comparative Example) | B | 1.585 | Silicon oxide | 1.45 | 90 | 1.1 × 10⁻⁴ |
| 416 (Present invention)) | D | 1.605 | Silicon nitride | 1.95 | 90 | 2.9 × 10⁻⁵ |
| 417 (Present invention) | D | 1.605 | Aluminum oxide | 1.63 | 90 | 3.8 × 10⁻⁵ |
| 418 (Comparative Example) | D | 1.605 | Silicon oxide | 1.45 | 90 | 8.7 × 10⁻⁵ |

Based on the above results, the samples in which an inorganic barrier layer of silicon dioxide of low refractive index was employed were found to exhibit much poorer barrier properties than the samples in which an inorganic barrier layer of aluminum oxide or silicon nitride of high refractive index was employed. The importance of an inorganic barrier layer of high refractive index, which is one of the elements of the present invention, is clear from the above results.

It was also found that even an inorganic barrier layer comprised of aluminum oxide exhibited good barrier properties so long as the refractive index was 1.60 or higher. However, inorganic barrier layers comprised of silicon nitride exhibited even higher barrier properties.

Additionally, when the rate of the decrease in the water vapor permeability was calculated from the above results with the organic layer in the form of the present invention, there were more than 50% decrease at an inorganic layer barrier thickness of 35 nm in the present invention,. more than 30% decrease at an inorganic barrier layer thickness of 13 nm, and more than 40% decrease at an inorganic barrier layer thickness of 90 nm. This indicated that the effect of the present invention was most pronounced near the 35 nm region of inorganic barrier layer thickness. Investigation by the present inventors has revealed that the most pronounced effect is achieved with an inorganic barrier layer with a thickness in the region of 20 to 50 nm.

### Evaluation of Organic EL Light-Emitting Element

Organic EL elements in which water vapor and oxygen produce defects known as dark spots were evaluated in order to evaluate barrier properties. First, an electrically conductive glass substrate (surface resistance 10 Ω/□ (Ω/sq., ohms per square)) with an ITO film was cleaned with 2-propanol and then treated for 10 minutes with UV-ozone. The following compound layers were then sequentially deposed by vacuum vapor deposition method on the substrate (anode).

### (First Hole Transport Layer)

Copper phthalocyanine: film thickness 10 nm

### (Second Hole Transport Layer)

N,N′-Diphenyl-N,N′-dinaphthylbenzidine: film thickness 40 nm

### (Light-Emitting Layer and Electron Transport Layer)

Tris(8-hydroxyquinolinato)aluminum: film thickness 60 nm

### (Electron Injection Layer)

Lithium fluoride: film thickness 1 nm

A cathode was formed thereover by depositing metallic aluminum to 100 nm, over which a silicon nitride film 3 μm in thickness was formed by parallel plate CVD to fabricate organic EL elements.

Next, using a thermosetting adhesive (Epotec 310, Daizo-Nichimori), the organic EL elements that had been fabricated were bonded to each of the gas barrier films prepared above with the barrier layer facing the organic EL element and heated for 3 hours at 65° C. to set the adhesive. Twenty elements of each of these sealed organic EL elements were prepared.

Immediately following preparation, a 7V voltage was applied with a source measure unit (SMU 2400, manufactured by Keithley Corp.) to the organic EL elements to cause them to emit light. Observation of the light-emitting surface profile by microscopy revealed that each of the elements was uniformly emitting light without dark spots.

Finally, each of the elements was statically placed for 24 hours in a dark room at 60° C. and 90% relative humidity, after which the light-emitting surface profile was observed. The ratio of elements in which large dark spots greater than 300 μm in diameter were observed was defined as the failure rate and a failure rate was calculated for each element. The failure rate for each of the elements of the present invention was good, at 5% or less.

### Preparation of Solar Cells

The gas barrier films prepared above were used to prepare solar cell modules. Specifically, standard cure-type ethylene-vinyl acetate copolymer was employed as the filler for solar cell modules. Amorphous silicon solar cells were sandwiched between 10 cm square sheets of reinforced glass coated with 450 μm of ethylene-vinyl acetate copolymer and filled. The gas barrier film was then positioned thereon to prepare a solar cell module. The positioning was conducted under conditions of 150° C. while drawing a vacuum for 3 minutes, and pressure was applied for 9 minutes. The solar cell modules, prepared by this method, functioned well and exhibited good electrical output characteristics even in an environment of 85° C. and 85% relative humidity.

### Preparation of a Sealing Bag

Sealing bags were prepared using the gas barrier films fabricated above. The substrate film side of the gas barrier film was fused by the heat seal method to a bag (polyethylene bag) comprised of resin film and a sealing bag was prepared. A drug in the form of Cefazolin sodium (manufactured by Otsuka Pharmaceutical Factory, Inc.) was sealed into the sealing bags obtained. The drug was stored for 6 months under conditions of 40° C. and 75% relative humidity. Evaluation of change in the color tone revealed almost no change.

### INDUSTRIAL APPLICABILITY

The gas barrier film of the present invention exhibits high barrier properties and transparence and can thus be applied to sealing the outer surface side of various electronic devices, preferably organic ELs and solar cells. Since it is possible to fabricate a gas barrier film of high heat and humidity durability, the barrier laminate of the present invention is preferably employed to protect electronic devices employed outdoors,

While the present invention has been described in detail and with reference to specific embodiments thereof, it will be apparent to one skilled in the art that various changes and modifications can be made therein without departing from the spirit and scope thereof. All the publications referred to in the present specification are expressly incorporated herein by reference in their entirety. The foregoing description of preferred embodiments of the invention has been presented for purposes of illustration and description, and is not intended to be exhaustive or to limit the invention to the precise form disclosed, The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below,

1. A barrier laminate, comprising:
an organic layer; and
an inorganic barrier layer adjacent to the organic layer,
wherein the organic layer comprises:
a polymer obtained by polymerizing a polymerizable compound having two or more polymerizable groups per molecule,
wherein the organic layer has a refractive index of 1.60 or higher,
wherein the refractive index of the inorganic barrier layer is 1.60 or higher, and
the polymerizable compound is a compound denoted by any one of general formulas (1) or (3) below: 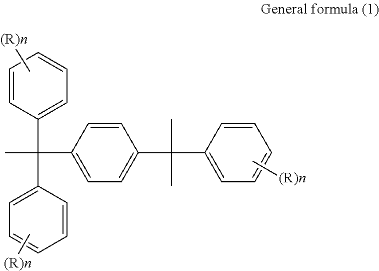
in general formula (1), each instance of R denotes a substituent, each of which may be identical to or different from the others, n denotes an integer of from 0 to 5, with at least one of the three instances of n denoting an integer of 1 or more, with each instance being identical to or different from the others, and at least one instance of R contains a polymerizable group; and 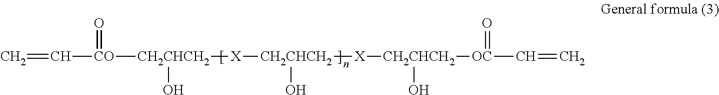
in general formula (3), X denotes a unit represented by formula (3a) below and n denotes an integer of from 0 to 20: 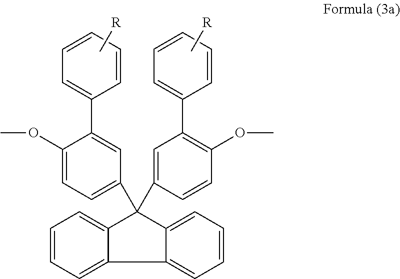
in formula (3a), R denotes hydrogen atom or a linear or branched alkyl group with 1 to 5 carbon atoms.

2. The barrier laminate according to claim 1, wherein the polymerizable compound is the compound denoted by general formula (1).

3. (canceled)

4. The barrier laminate according to claim 1, wherein the polymerizable compound is the compound denoted by general formula (3).

5. The barrier laminate according to claim 1, wherein the inorganic barrier layer comprises silicon oxide, silicon nitride, silicon carbide, or a mixture thereof.

6. The barrier laminate according to claim 1, wherein the organic layer is a layer formed from a polymerizable composition comprising a silane coupling agent.

7. The barrier laminate according to claim 2, wherein the organic layer is a layer formed from a polymerizable composition comprising a silane coupling agent.

8. (canceled)

9. The barrier laminate according to claim 4, wherein the organic layer is a layer formed from a polymerizable composition comprising a silane coupling agent.

10. The barrier laminate according to claim 1, wherein at least two layers of the organic layer and at least two layers of the inorganic barrier layer are laminated in alternating fashion.

11. The barrier laminate of claim 6, wherein at least two layers of the organic layer and at least two layers of the inorganic barrier layer are laminated in alternating fashion.

12. A gas barrier film having the barrier laminate according to claim 1 on a substrate film.

13. A device comprising the barrier laminate according to claim 1.

14. The device according to claim 13, wherein the device is an electronic device.

15. An organic EL element or a solar cell element, comprising the barrier laminate according to claim 1

16. An organic EL element or a solar cell element, comprising the barrier laminate according to claim 2.

17. (canceled)

18. An organic EL element or a solar cell element, comprising the barrier laminate according to claim 4.

19. A sealing bag comprising the barrier laminate according to claim 1.

20. A sealing bag comprising the barrier laminate according to claim 6.

21. The barrier laminate according to claim 1, wherein the polymerizable compound is a compound denoted by general formulas (2) or (3), 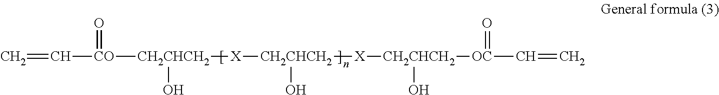
in general formula (3), X denotes a unit represented by formula (3a) below and n denotes an integer of from 0 to 20: 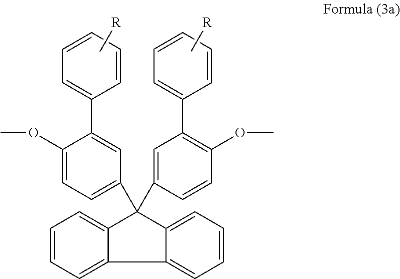
in formula (3a), R denotes hydrogen atom; and 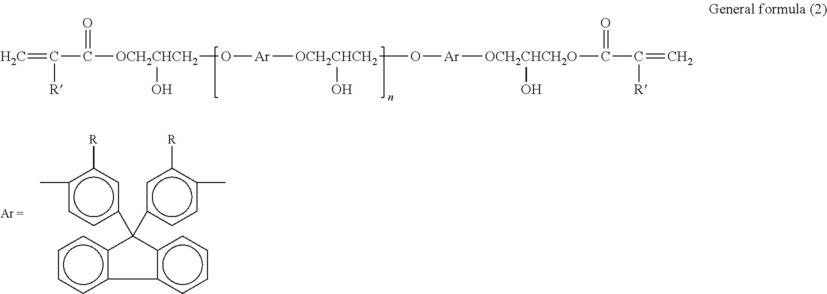
in general formula (2) each R is a non-substituted phenyl group and R′ is hydrogen atom.
